(19) United States
(12) Patent Application Publication
(10) Pub. No.: US 2025/0194104 A1
(43) Pub. Date: Jun. 12, 2025

(54) DOUBLE-SIDED MEMORY DEVICE USING A SHARED TRANSISTOR

(71) Applicant: International Business Machines Corporation, Armonk, NY (US)

(72) Inventors: Ashim Dutta, Clifton Park, NY (US); Shravana Kumar Katakam, Lehi, UT (US); Eric Raymond Evarts, Niskayuna, NY (US); Ruilong Xie, Niskayuna, NY (US); Chih-Chao Yang, Glenmont, NY (US)

(21) Appl. No.: 18/533,589

(22) Filed: Dec. 8, 2023

(51) Int. Cl. H10B 61/00

(52) U.S. Cl. CPC H10B 61/22

(57) ABSTRACT

A semiconductor device comprises a first memory cell disposed on a first side of the semiconductor device and connected to a transistor, and a second memory cell disposed on a second side of the semiconductor device and connected to the transistor. The first side of the semiconductor device is on top of the transistor and the second side of the semiconductor device is under the transistor.

### BACKGROUND

The present application relates to semiconductors, and more specifically, to techniques for forming semiconductor structures. Semiconductors and integrated circuit chips have become ubiquitous within many products, particularly as they continue to decrease in cost and size. There is a continued desire to reduce the size of structural features and/or to provide a greater amount of structural features for a given chip size. Miniaturization, in general, allows for increased performance at lower power levels and lower costs. Present technology is at or approaching atomic level scaling of certain micro-devices such as logic gates, field-effect transistors (FETs), and capacitors.

### SUMMARY

Embodiments of the invention provide structures for and techniques for forming a double-sided 2-bit magnetoresistive random access memory (MRAM) device.

In one embodiment, a semiconductor device includes a first memory cell disposed on a first side of the semiconductor device and connected to a transistor, and a second memory cell disposed on a second side of the semiconductor device and connected to the transistor. The first side of the semiconductor device is on top of the transistor and the second side of the semiconductor device is under the transistor.

As may be combined with the preceding paragraph, the first memory cell may include a first MRAM cell connected to a first bit line, and the second memory cell may include a second MRAM cell connected to a second bit line.

As may be combined with the preceding paragraphs, the transistor may include a source/drain region. The semiconductor device may further include a first source/drain contact disposed on a first side of the source/drain region on the first side of the semiconductor device, and a second source/drain contact disposed on a second side of the source/drain region on the second side of the semiconductor device. The first memory cell may be connected to the transistor through the first source/drain contact, and the second memory cell may be connected to the transistor through the second source/drain contact. The transistor may include a nanosheet transistor.

As may be combined with the preceding paragraphs, the first side of the semiconductor device may include a frontside of the semiconductor device, and the second side of the semiconductor device may include a backside of the semiconductor device. A first selector device may correspond to the first memory cell, wherein the first selector device is configured to permit current to flow from the first memory cell to the transistor when voltage applied to the first selector device is greater than or equal to a threshold activation voltage. A second selector device may correspond to the second memory cell, wherein the second selector device is configured to permit current to flow from the second memory cell to the transistor when voltage applied to the second selector device is greater than or equal to the threshold activation voltage.

As may be combined with the preceding paragraphs, the first selector device may be disposed on the first side of the semiconductor device, and the second selector device may be disposed on the second side of the semiconductor device. The first selector device may be disposed between a bottom electrode of the first memory cell and a bottom electrode contact corresponding to the first memory cell, and may be self-aligned with the bottom electrode of the first memory cell. The second selector device may be disposed between a bottom electrode of the second memory cell and a bottom electrode contact corresponding to the second memory cell, and may be self-aligned with the bottom electrode of the second memory cell. The first selector device may be disposed between a bottom electrode of the first memory cell and a reference layer of the first memory cell, and the second selector device may be disposed between a bottom electrode of the second memory cell and a reference layer of the second memory cell. The first selector device may be disposed between a top electrode of the first memory cell and a free layer of the first memory cell, and the second selector device may be disposed between a top electrode of the second memory cell and a free layer of the second memory cell.

As may be combined with the preceding paragraphs, the transistor may be a shared transistor, and a top electrode of the first memory cell may be connected to a first transistor different from the shared transistor through a first conductive line on the first side of the semiconductor device. A top electrode of the second memory cell may be connected to a second transistor different from the first transistor and the shared transistor through a second conductive line on the second side of the semiconductor device.

Advantageously, a 2-bit MRAM cell architecture uses one common (shared) transistor for two MRAM cells to independently perform write operations. One of the MRAM cells is disposed on a frontside and the other MRAM cell is disposed on the backside of the wafer opposite to the frontside. As a result, a total number of required transistors can be reduced, such that larger sized transistors can be included in a semiconductor structure to provide higher drive currents. As an additional advantage, the placement of MRAM cells on opposite sides of wafers allows for increases in memory density at a given pitch.

In another embodiment, a semiconductor device includes a first magnetoresistive random access memory cell disposed on a first side of the semiconductor device and connected to a first side of a source/drain region of a transistor, and a second magnetoresistive random access memory cell disposed on a second side of the semiconductor device and connected to a second side of the source/drain region of the transistor. The first side of the semiconductor device is on top of the transistor and the second side of the semiconductor device is under the transistor. The first side of the source/drain region corresponds to the first side of the semiconductor device, and the second side of the source/drain region corresponds to the second side of the semiconductor device.

As may be combined with the preceding paragraphs, the first side of the semiconductor device may include a frontside of the semiconductor device, and the second side of the semiconductor device includes a backside of the semiconductor device. The first selector device may correspond to the first MRAM cell, wherein the first selector device is configured to permit current to flow from the first MRAM cell to the transistor when voltage applied to the first selector device is greater than or equal to a threshold activation voltage. The second selector device may correspond to the second MRAM cell, wherein the second selector device is configured to permit current to flow from the second MRAM cell to the transistor when voltage applied to the second selector device is greater than or equal to the threshold activation voltage.

As may be combined with the preceding paragraphs, the first selector device may be disposed on the first side of the semiconductor device and is aligned with at least a bottom electrode of the first MRAM cell, and the second selector device may be disposed on the second side of the semiconductor device and is aligned with at least a bottom electrode of the second MRAM cell.

As may be combined with the preceding paragraphs, the transistor may be a shared transistor, a top electrode of the first MRAM cell is connected to a first transistor different from the shared transistor through a first conductive line on the first side of the semiconductor device, and a top electrode of the second MRAM cell is connected to a second transistor different from the first transistor and the shared transistor through a second conductive line on the second side of the semiconductor device.

In another embodiment, a semiconductor device includes a stacked structure comprising a transistor, a first memory cell stacked over the transistor, and a second memory cell stacked under the transistor. The transistor is connected to the first memory cell and to the second memory cell. The first memory cell is disposed on a first side of the semiconductor device and the second memory cell is disposed on a second side of the semiconductor device.

As may be combined with the preceding paragraphs, the transistor may include a source/drain region, and the semiconductor device may further include a first source/drain contact disposed on a first side of the source/drain region on the first side of the semiconductor device, and a second source/drain contact disposed on a second side of the source/drain region on the second side of the semiconductor device. The first memory cell may be connected to the transistor through the first source/drain contact, and the second memory cell may be connected to the transistor through the second source/drain contact.

As may be combined with the preceding paragraphs, the first side of the semiconductor device may include a frontside of the semiconductor device, and the second side of the semiconductor device may include a backside of the semiconductor device. The transistor may be a shared transistor. A top electrode of the first memory cell may be connected to a first transistor different from the shared transistor through a first conductive line on the first side of the semiconductor device, and a top electrode of the second memory cell may be connected to a second transistor different from the first transistor and the shared transistor through a second conductive line on the second side of the semiconductor device.

These and other features and advantages of embodiments described herein will become more apparent from the accompanying drawings and the following detailed description.

### BRIEF DESCRIPTION OF THE DRAWINGS

FIG. 1 depicts a cross-sectional view illustrating stacked semiconductor nanosheet layers, according to an embodiment of the invention.

FIG. 2 depicts a cross-sectional view following patterning of stacked semiconductor nanosheet layers and isolation region formation, according to an embodiment of the invention.

FIG. 3 depicts a cross-sectional view following gate spacer formation, lateral recessing of sacrificial semiconductor layers, inner spacer formation, source/drain region formation, inter-layer dielectric (ILD) layer formation, and replacement metal gate (RMG) formation, according to an embodiment of the invention.

FIG. 4 depicts a cross-sectional view following additional ILD layer formation, frontside source/drain contact formation and frontside gate contact formation, according to an embodiment of the invention.

FIG. 5 depicts a cross-sectional view following frontside via formation, frontside metallization layer formation and frontside bottom electrode contact formation, according to an embodiment of the invention.

FIG. 6 depicts a cross-sectional view following formation of frontside memory stack layers, according to an embodiment of the invention.

FIG. 7 depicts a cross-sectional view following patterning of frontside memory stack layers to form a frontside memory pillar, according to an embodiment of the invention.

FIG. 8 depicts a cross-sectional view following additional via formation and additional metallization layer formation, according to an embodiment of the invention.

FIG. 9 depicts a cross-sectional view following back-end-of-line (BEOL) interconnect formation, according to an embodiment of the invention.

FIG. 10 depicts a cross-sectional view following carrier wafer bonding, according to an embodiment of the invention.

FIG. 11 depicts a cross-sectional view following wafer flipping, according to an embodiment of the invention.

FIG. 12 depicts a cross-sectional view following semiconductor substrate and etch stop layer removal, according to an embodiment of the invention.

FIG. 13 depicts a cross-sectional view following remaining semiconductor substrate removal, backside ILD layer formation and backside source/drain contact formation, according to an embodiment of the invention.

FIG. 14 depicts a cross-sectional view following backside via formation, backside metallization layer formation, backside memory pillar formation and carrier wafer removal, according to an embodiment of the invention.

FIG. 15 depicts a circuit diagram of a double-sided 2-bit MRAM architecture, according to an embodiment of the invention.

FIG. 16 depicts a cross-sectional view combined with a circuit diagram illustrating a double-sided 2-bit MRAM architecture, according to an embodiment of the invention.

FIGS. 17A-17C depict cross-sectional views with different memory cell and selector device configurations, according to an embodiment of the invention.

### DETAILED DESCRIPTION

Illustrative embodiments of the invention may be described herein in the context of illustrative methods for forming a double-sided 2-bit MRAM device, along with illustrative apparatus, systems and devices formed using such methods. However, it is to be understood that embodiments of the invention are not limited to the illustrative methods, apparatus, systems and devices but instead are more broadly applicable to other suitable methods, apparatus, systems and devices.

It is to be understood that the various features shown in the accompanying drawings are schematic illustrations that are not necessarily drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the terms “exemplary” and “illustrative” as used herein mean “serving as an example, instance, or illustration.” Any embodiment or design described herein as “exemplary” or “illustrative” is not to be construed as preferred or advantageous over other embodiments or designs.

A field-effect transistor (FET) is a transistor having a source, a gate, and a drain, and having action that depends on the flow of carriers (electrons or holes) along a channel that runs between the source and drain. Current through the channel between the source and drain may be controlled by a transverse electric field under the gate.

FETs are widely used for switching, amplification, filtering, and other tasks. FETs include metal-oxide-semiconductor (MOS) FETs (MOSFETs). Complementary MOS (CMOS) devices are widely used, where both n-type and p-type transistors (nFET and pFET) are used to fabricate logic and other circuitry. Source and drain regions of a FET are typically formed by adding dopants to target regions of a semiconductor body on either side of a channel, with the gate being formed above the channel. The gate includes a gate dielectric over the channel and a gate conductor over the gate dielectric. The gate dielectric is an insulator material that prevents large leakage current from flowing into the channel when voltage is applied to the gate conductor while allowing applied gate voltage to produce a transverse electric field in the channel.

Various techniques may be used to reduce the size of FETs. One technique is through the use of fin-shaped channels in FinFET devices. Before the advent of FinFET arrangements, CMOS devices were typically substantially planar along the surface of the semiconductor substrate, with the exception of the FET gate disposed over the top of the channel. FinFETs utilize a vertical channel structure, increasing the surface area of the channel exposed to the gate. Thus, in FinFET structures, the gate can more effectively control the channel, as the gate extends over more than one side or surface of the channel. In some FinFET arrangements, the gate encloses three surfaces of the three-dimensional channel, rather than being disposed over just the top surface of a traditional planar channel.

Another technique useful for reducing the size of FETs is through the use of stacked nanosheet channels formed over a semiconductor substrate. Stacked nanosheets may be two-dimensional nanostructures, such as sheets having a thickness range on the order of 1 to 100 nanometers (nm). Nanosheets and nanowires are viable options for scaling to 7 nm and beyond. A general process flow for formation of a nanosheet stack involves selectively removing sacrificial layers, which may be formed of silicon germanium (SiGe), between sheets of channel material, which may be formed of silicon (Si).

For continued scaling (e.g., to 2.5 nm and beyond), next-generation stacked FET devices may be used. Next-generation stacked FET devices provide a complex gate-all-around (GAA) structure. Conventional GAA FETs, such as nanosheet FETs, may stack multiple p-type nanowires or nanosheets on top of each other in one device, and may stack multiple n-type nanowires or nanosheets on top of each other in another device. Next-generation stacked FET structures provide improved track height scaling, leading to structural gains (e.g., such as 30-40% structural gains for different types of devices, such as logic devices, static random-access memory (SRAM) devices, etc.). In next-generation stacked FET structures, n-type and p-type nanowires or nanosheets are stacked on each other, eliminating n-to-p separation bottlenecks and reducing the device area footprint. There is, however, a continued desire for further scaling and reducing the size of FETs.

As discussed above, various techniques may be used to reduce the size of FETs, including through the use of fin-shaped channels in FinFET devices, through the use of stacked nanosheet channels formed over a semiconductor substrate, and next-generation stacked FET devices. Although embodiments of the present invention are discussed in connection with nanosheet stacks, the embodiments of the present invention are not necessarily limited thereto, and may similarly apply to nanowire stacks.

Certain integration schemes require memory elements in the back-end-of-line (BEOL). Such memory elements may be formed in a column or pillar shape. The memory elements are included in memory devices such as, for example, phase-change random-access memory (PCRAM), resistive random-access memory (RRAM or ReRAM), and magnetoresistive random access memory (MRAM) devices.

Current memory devices, such as, for example, single bit MRAM devices, use one transistor for each MRAM cell to perform write operations. These transistors must be large to support required driving current, which poses limits to scaling.

Illustrative embodiments provide a 2-bit MRAM cell architecture that uses one shared transistor for 2 MRAM cells to perform write operations. One of the MRAM cells is on a frontside of a semiconductor structure and the other one of the MRAM cells is on the backside of the semiconductor structure. This configuration reduces a total number of transistors and, as a result, allows for larger size transistors to provide higher drive currents. Locating MRAM cells on opposite sides of wafers permits increases in memory density at a given pitch.

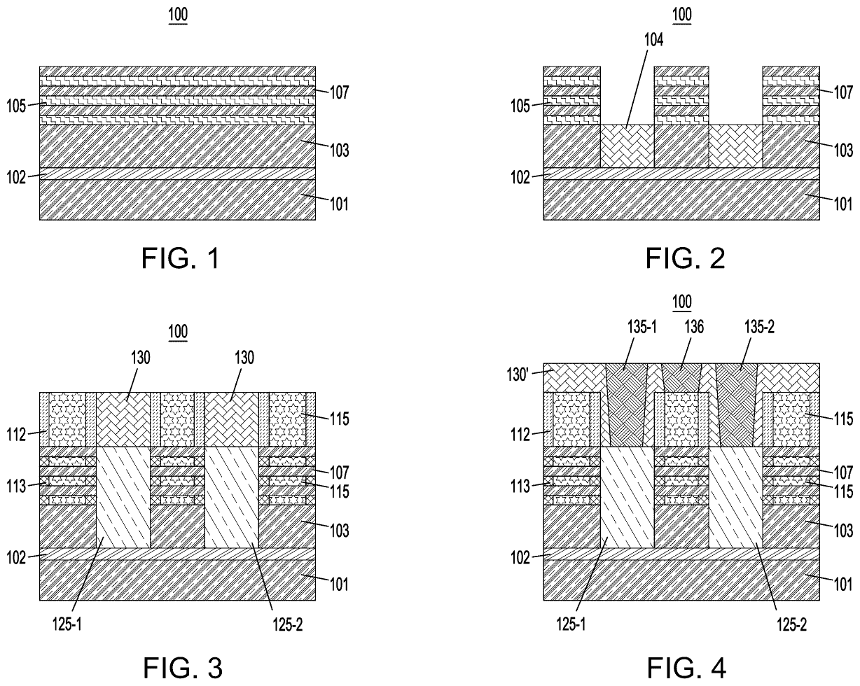

FIG. 1 depicts a cross-sectional view of a semiconductor structure 100 including a stacked structure of sacrificial layers 105 and channel layers 107. In an illustrative embodiment, the sacrificial layers 105 include silicon germanium (SiGe) and the channel layers 107 include silicon. In illustrative embodiments, the sacrificial layers 105 include a germanium concentration of about 30% (e.g., SiGe30), but the embodiments are not necessarily limited to SiGe30 for the sacrificial layers 105.

A first semiconductor substrate 101 and a second semiconductor substrate 103 include semiconductor material including, but not limited to, silicon, III-V, II-V compound semiconductor materials or other like semiconductor materials. In addition, multiple layers of the semiconductor materials can be used as the semiconductor material of the first and second semiconductor substrates 101 and 103. An etch stop layer 102 is formed on the first semiconductor substrate 101. In an illustrative embodiment, the etch stop layer 102 includes SiGe (e.g., SiGe30) or silicon dioxide (SiO₂) and the first and second semiconductor substrates 101 and 103 include silicon.

According to one or more embodiments, the etch stop layer 102 is epitaxially grown on the first semiconductor substrate 101, and the second semiconductor substrate 103 is epitaxially grown on the etch stop layer 102. The sacrificial layers 105 and channel layers 107 are epitaxially grown from underlying layers in an alternating and stacked configuration. A first one of the sacrificial layers 105 is followed by a first one of the channel layers 107 on the first one of the sacrificial layers 105, which is followed by a second one of the sacrificial layers 105 on the first one of the channel layers 107, and so on. As can be understood, the sacrificial layers 105 and channel layers 107 are epitaxially grown from their corresponding underlying semiconductor layers.

The embodiments are not necessarily limited to the shown number of sacrificial layers 105 and channel layers 107, and there may be more or less layers in the same alternating configuration depending on design constraints. The sacrificial layers 105, as described further herein, are eventually removed and replaced by gate structures. Although SiGe is described as a sacrificial material for sacrificial layers 105, other materials can be used as long as the sacrificial layers 105 have the property of being able to be removed selectively compared to the material of the channel layers 107.

The terms “epitaxial growth and/or deposition” and “epitaxially formed and/or grown,” mean the growth of a semiconductor material (crystalline material) on a deposition surface of another semiconductor material (crystalline material), in which the semiconductor material being grown (crystalline over layer) has substantially the same crystalline characteristics as the semiconductor material of the deposition surface (seed material). In an epitaxial deposition process, the chemical reactants provided by the source gases are controlled, and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed.

The epitaxial deposition process may employ the deposition chamber of a chemical vapor deposition type apparatus, such as a metal-organic chemical vapor deposition (MOCVD), rapid thermal chemical vapor deposition (RTCVD), ultra-high vacuum chemical vapor deposition (UHVCVD), or a low-pressure chemical vapor deposition (LPCVD) apparatus. A number of different sources may be used for the epitaxial deposition of the in situ doped semiconductor material. In some embodiments, the gas source for the deposition of an epitaxially formed semiconductor material may include silicon (Si) deposited from silane, disilane, trisilane, tetrasilane, hexachlorodisilane, tetrachlorosilane, dichlorosilane, trichlorosilane, and combinations thereof. In other examples, when the semiconductor material includes germanium, a germanium gas source may be selected from the group consisting of germane, digermane, halogermane, dichlorogermane, trichlorogermane, tetrachlorogermane and combinations thereof. The temperature for epitaxial deposition typically ranges from 450° C. to 900° C. Although higher temperature typically results in faster deposition, the faster deposition may result in crystal defects and film cracking.

In a non-limiting illustrative embodiment, a height of the sacrificial layers 105 can be in the range of about 6 nm to about 15 nm depending on the application of the device. Also, in a non-limiting illustrative embodiment, a height of the channel layers 107 can be in the range of about 6 nm to about 15 nm depending on the desired process and application. In accordance with an embodiment of the present invention, each of the channel layers 107 has the same or substantially the same composition and size as each other, and each of the sacrificial layers 105 has the same or substantially the same composition and size as each other.

As used herein, “frontside or “first side” refers to a side on top of the second semiconductor substrate 103 and/or in front of, on top of or in an upward direction from the stacked nanosheet/gate and channel layers of the transistors in the orientation shown in the cross-sectional figures. As used herein, “backside” or “second side” refers to a side below the semiconductor substrate 103 and/or behind, under, below or in a downward direction from the stacked nanosheet/gate and channel layers of the transistors in the orientation shown in the cross-sectional figures (e.g., opposite the “frontside”).

Referring to FIG. 2, portions of the nanosheet stacks comprising the sacrificial layers 105 and channel layers 107 are removed, and portions of the second semiconductor substrate 103 are recessed. Isolation regions 104 (e.g., shallow trench isolation (STI)) regions are formed between the remaining nanosheet stacks in the recessed portions of the second semiconductor substrate 103. As explained in more detail herein, other portions of the second semiconductor substrate 103 will be recessed and source/drain regions will be formed in other recessed portions of the second semiconductor substrate 103. Isolation regions 104 comprising dielectric material fill in the recessed portions of the second semiconductor substrate 103. The dielectric material may include, for example, silicon nitride (SiN), silicon oxynitride (SiON), silicon-carbon-nitride (SiCN), boron nitride (BN), silicon boron nitride (SiBN), silicoboron carbonitride (SiBCN), silicon oxycarbonitride (SiOCN) and combinations thereof, and is deposited using deposition techniques such as, for example, chemical vapor deposition (CVD), plasma enhanced CVD (PECVD), radio-frequency CVD (RFCVD), physical vapor deposition (PVD), atomic layer deposition (ALD), molecular beam deposition (MBD), pulsed laser deposition (PLD), and/or liquid source misted chemical deposition (LSMCD).

Dummy gate portions (not shown) are formed on the uppermost channel layers 107 and around the stacked nanosheet configurations of the sacrificial layers 105 and channel layers 107. The dummy gate portions include, but are not necessarily limited to, an amorphous silicon (a-Si) layer. The dummy gate portions are deposited using deposition techniques such as, for example, CVD, PECVD, RFCVD, PVD, ALD, MBD, PLD, LSMCD, sputtering and/or plating, followed by a planarization process, such as, chemical mechanical planarization (CMP), and lithography and etching steps to remove excess dummy gate material, and pattern the deposited layer. Hardmask layers (not shown) are formed on the dummy gate portions. The hardmask layers include, for example, a nitride such as SiN or other nitride material.

Gate spacers 112 (see FIG. 3) are formed on sides of the hardmask layers and dummy gate portions (which are later replaced by gate structures 115) by one or more of the deposition techniques noted in connection with deposition of the dummy gate material. The spacer material can include for example, one or more dielectrics, including, but not necessarily limited to, SiN, SiON, SiOC, SiCN, BN, SiBN, SiBCN, SiOCN, SiOₓ, and combinations thereof. According to an embodiment, the hardmask layers and gate spacers 112 can be the same material or different materials. The gate spacers 112 can be formed by any suitable techniques such as deposition followed by directional etching. Deposition may include, but is not limited to, ALD or CVD. Directional etching may include but is not limited to, reactive ion etching (RIE).

Exposed portions of the stacked sacrificial layers 105 and channel layers 107, which are not under the hardmask layers, gate spacers 112 and dummy gate portions, are removed using, for example, an etching process, such as RIE, where the hardmask layers, gate spacers 112 and dummy gate portions are used as a mask. The portions of the stacked structures of the sacrificial layers 105 and channel layers 107 under the hardmask layers, gate spacers 112 and under the dummy gate portions remain after the etching process, and portions of the sacrificial layers 105 and channel layers 107 in areas that correspond to where source/drain regions will be formed are removed.

Referring to FIG. 3, due to, for example, germanium in the sacrificial layers 105, lateral etching of the sacrificial layers 105 can be performed selective to the channel layers 107, such that the side portions of the sacrificial layers 105 can be removed to create vacant areas to be filled in by inner spacers 113. The material of the inner spacers 113 can include, but is not necessarily limited to, a nitride, such as, SiN, SiON, SiCN, BN, SiBN, SiBCN or SiOCN. Gate spacers 112 are positioned on the nanosheet stacks on opposite lateral sides of the dummy gate portions (which are later replaced by gate structures 115). In an illustrative embodiment, the gate spacers 112 are formed from the same or similar material to that of the inner spacers 113. Like the gate spacers 112, the inner spacers 113 can be formed by any suitable techniques such as deposition followed by directional etching.

As noted herein above, other portions of the second semiconductor substrate 103 adjacent the isolation regions 104 are recessed in areas where source/drain regions 125-1 and 125-2 (collectively “source/drain regions 125”) will be formed. As can be understood, the cross-section in FIG. 2 is taken along a different line than the cross-section in FIG. 3 and the subsequent cross-sectional views, which do not illustrate the isolation regions 104. Referring to FIG. 3, the source/drain regions 125 are epitaxially grown between the nanosheet stacks from exposed portions of the second semiconductor substrate 103 and from exposed side surfaces of the channel layers 107. The isolation regions 104 (not shown in FIG. 3) are disposed around one or more sides of the bottom portions of the source/drain regions 125. Side surfaces of respective ones of the channel layers 107 contact a side surface at least one adjacent source/drain region 125. The top surfaces of the source/drain regions 125 are above the top surfaces of uppermost ones of the channel layers 107.

According to a non-limiting embodiment of the present invention, the conditions of the epitaxial growth process for the source/drain regions 125 are, for example, RTCVD epitaxial growth using SiH₄, SiH₂Cl₂, GeH₄, CH₃SiH₃, B₂H₆, PF₃, and/or H₂ gases with temperature and pressure ranges of about 450° C. to about 800° C., and about 5 Torr-about 300 Torr. In the case of n-type FETS (nFETs), the source/drain regions 125 can include silicon doped with n-type dopants including, for example, phosphorus (P), arsenic (As) and antimony (Sb). In the case of p-type FETS (pFETs), the source/drain regions 125 can include silicon doped with n-type dopants including, for example, boron (B), boron fluoride (BF₂), gallium (Ga), indium (In), and thallium (Tl).

An inter-layer dielectric (ILD) layer 130 is deposited to fill in portions on and around the source/drain regions 125. The ILD layer 130 is deposited using deposition techniques such as, for example, CVD, PECVD, RFCVD, PVD, ALD, MBD, PLD, and/or LSMCD, followed by a planarization process, such as, chemical mechanical planarization (CMP) to remove excess portions of the ILD layer 130 deposited on top of the hardmask layers and gate spacers 112, and to remove the hardmask layers and portions of the gate spacers 112 to expose the dummy gate portions. The ILD layer 130 may include, for example, SiOx, SiOC, SiOCN or some other dielectric.

Dummy gate portions are selectively removed to create vacant areas where gate structures 115 will be formed in place of the dummy gate portions. The selective removal can be performed using, for example, hot ammonia to remove a-Si. In addition, the sacrificial layers 105 are selectively removed to create vacant areas where the gate structures 115 will be formed in place of the sacrificial layers 105. The sacrificial layers 105 are selectively removed with respect to the channel layers 107. The selective removal can be performed using, for example, a dry HCl etch.

Following removal of the dummy gate portions and sacrificial layers 105, the channel layers 107 are suspended, and gate structures 115, including, for example, gate and dielectric portions are formed in the vacant portions left by removal of the dummy gate portions, and the sacrificial layers 105. In illustrative embodiments, each gate structure 115 includes a gate dielectric layer such as, for example, a high-K dielectric layer including, but not necessarily limited to, HfO₂ (hafnium oxide), ZrO₂ (zirconium dioxide), hafnium zirconium oxide, Al₂O₃ (aluminum oxide), and Ta₂O₅ (tantalum oxide). Examples of high-k materials also include, but are not limited to, metal oxides such as hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate. According to an embodiment, the gate structures 115 each include a metal gate portion including a work-function metal (WFM) layer, including but not necessarily limited to, for a pFET, titanium nitride (TiN), tantalum nitride (TaN) or ruthenium (Ru), and for an nFET, TiN, titanium aluminum nitride (TiAlN), titanium aluminum carbon nitride (TiAlCN), titanium aluminum carbide (TiAlC), tantalum aluminum carbide (TaAlC), tantalum aluminum carbon nitride (TaAlCN) or lanthanum (La) doped TiN, TaN, which can be deposited on the gate dielectric layer. The metal gate portions can also each further include a gate metal layer including, but not necessarily limited to, metals, such as, for example, tungsten, cobalt, zirconium, tantalum, titanium, aluminum, ruthenium, copper, metal carbides, metal nitrides, transition metal aluminides, tantalum carbide, titanium carbide, tantalum magnesium carbide, or combinations thereof deposited on the WFM layer and the gate dielectric layer. It should be appreciated that various other materials may be used for the metal gate portions as desired.

Referring to FIG. 4, additional ILD material is deposited to form an additional ILD layer 130′ on top of the ILD layer 130. Then, frontside source/drain contacts 135-1 and 135-2 (collectively “frontside source/drain contacts 135”) are formed in the ILD layers 130 and 130′. In forming the frontside source/drain contacts 135, openings are formed through portions of the ILD layers 130 and 130′. The openings expose portions the source/drain regions 125 on which the frontside source/drain contacts 135 are to be formed. According to an embodiment, masks are formed on parts of the additional ILD layer 130′, and exposed portions of the ILD layers 130 and 130′ corresponding to where the openings are to be formed are removed using, for example, a dry etching process using a RIE or ion beam etch (IBE) process, a wet chemical etch process or a combination of these etching processes. A dry etch may be performed using a plasma. Such wet or dry etch processes include, for example, IBE by Ar/CHF3 based chemistry.

Metal layers are deposited in the openings to form the frontside source/drain contacts 135. The metal layers include, for example, a silicide layer, such as Ni, Ti, NiPt, etc., a metal adhesion layer, such as TiN, and a conductive metal fill layer, such as W, Al, Co, Ru, etc., and can be deposited using, for example, a deposition technique such as CVD, PECVD, RFCVD, PVD, ALD, MBD, PLD, LSMCD, sputtering and/or plating, followed by a planarization process such as, CMP to remove excess portions of the metal layers from on top of the additional ILD layer 130′.

The frontside source/drain contacts 135-1 and 135-2 contact respective ones of the source/drain regions 125-1 and 125-2 at front sides of the source/drain regions 125. The frontside source/drain contacts 135 extend through the ILD layers 130 and 130′ to land on and contact the corresponding source/drain regions 125. A frontside gate contact 136 is formed through the additional ILD layer 130′ to land on and contact a corresponding gate structure 115. The process and materials used for forming the frontside gate contact 136 is similar to those used for forming the frontside source/drain contacts 135.

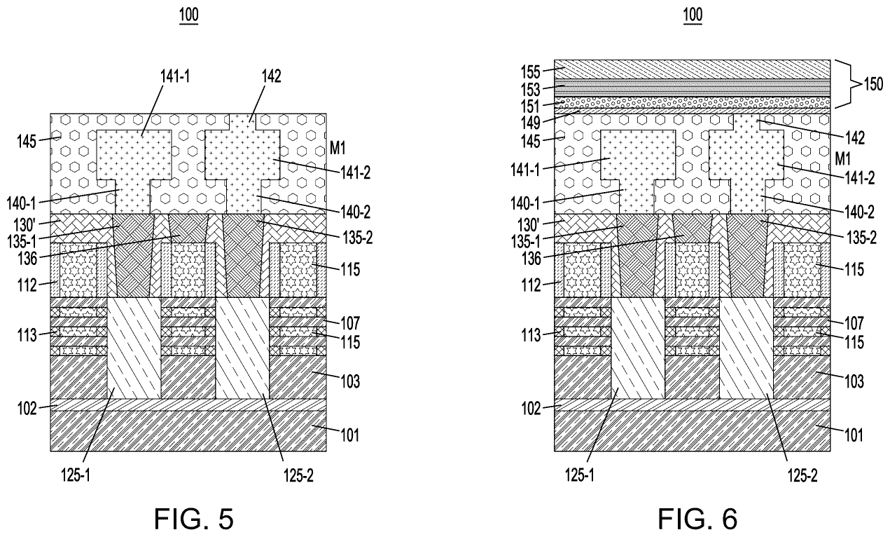

Referring to FIG. 5, one or more dielectric layers 145 are formed on the FIG. 4 structure. In an illustrative embodiment, the one or more dielectric layers 145 include, for example, one or more layers of, for example, SiOₓ, SiOC, ultra-low-k dielectrics or some other dielectric formed on a cap layer comprising for example, NBLoK™ material, a nitride material (e.g., SiN, SiCN), SiC or other suitable material. NBLoK™ material is from Applied Materials, Inc. of Santa Clara, CA, and is a nitrogen-doped silicon carbide. The cap layer may be formed on another dielectric layer including, for example, SiO₂, carbon-doped silicon oxide (SiCOH), SILK® dielectrics, tetraethyl orthosilicate (TEOS), and/or porous forms of these low-k and ultra-low-k dielectric films. The one or more dielectric layers 145 are deposited using deposition techniques such as, for example, CVD, PECVD, RFCVD, PVD, ALD, MBD, PLD, and/or LSMCD, followed by a planarization process, such as, for example, CMP.

A metallization level M1 formed in the one or more dielectric layers 145 includes frontside M1 contacts 141-1 and 141-2 (collectively “frontside M1 contacts 141”) each comprising, for example, a fill layer and a liner layer. The fill layers are formed on the liner layers. The liner layers include, for example, niobium (Nb), niobium nitride (NbN), tungsten (W), tungsten nitride (WN), tantalum (Ta), tantalum nitride (TaN), titanium (Ti), titanium nitride (TiN), ruthenium (Ru), molybdenum (Mo), chromium (Cr), vanadium (V), palladium (Pd), platinum (Pt), rhodium (Rh), scandium (Sc), aluminum (Al) and other high melting point metals or conductive metal nitrides. The liner layers are conformally formed on sidewalls and a bottom surface of a trench in the one or more dielectric layers 145. The fill layers include an electrically conductive metal, such as, for example, tungsten, cobalt (Co), zirconium (Zr), tantalum (Ta), titanium (Ti), aluminum (Al), ruthenium (Ru), copper (Cu), metal carbides (e.g., tantalum carbide, titanium carbide, tantalum magnesium carbide), metal nitrides (e.g., titanium nitride), transition metal aluminides or combinations thereof. The liner and fill layers are deposited using, for example, one or more deposition techniques, such as, but not necessarily limited to, CVD, PECVD, RFCVD, PVD, ALD, MBD, PLD, LSMCD and/or sputtering, which can be followed by a planarization process such as, for example, CMP.

Contacts, also referred to herein as wires or conductive lines, function as electrically conductive contacts or interconnects. The contacts form electrical connections between elements and/or devices, or to elements or devices. As used herein, a “contact” or “contact structure” includes a conductive fill layer, and may further include a liner layer. First frontside vias 140-1 and 140-2 (collectively “first frontside vias 140”), each comprising a fill layer and a liner layer the same or similar to the fill and liner layers for the frontside M1 contacts 141, extend from the frontside M1 contacts 141 to connect to the frontside source/drain contacts 135-1 and 135-2.

A frontside bottom electrode contact 142 is formed in the one or more dielectric layers 145 on the frontside M1 contact 141-2. The frontside bottom electrode contact 142 is a contact for a bottom electrode of a frontside memory device that is subsequently formed on the frontside bottom electrode contact 142. Similar to the frontside M1 contacts 141, the frontside bottom electrode contact 142 includes a fill layer and a liner layer comprising the same or similar materials to those of the previously described fill and liner layers. The frontside bottom electrode contact 142 is formed by etching portions of the one or more dielectric layers 145 over the frontside M1 contact 141-2 to form a trench in which the liner layer and the fill layer are deposited to fill in the trench.

Referring to FIG. 6, a selector device layer 149 and a plurality of memory device layers 150 including a bottom electrode layer 151, memory element layers 153 (e.g., MTJ layers) and a top electrode layer 155 are deposited on the structure of FIG. 5. The selector device layer 149 includes selector switch material including, but not necessarily limited to, for example, SiOₓ, TiOₓ, AlOₓ, WOₓ, TiNOₓ, HfOₓ, TaOₓ, NbOₓ, etc. or a diode material with desired characteristics. The bottom electrode layer 151 and the top electrode layer 155 include, for example, TaN, TiN, Nb, NbN, W, WN, Ta, Ti, Ru, Mo, Cr, V, Pd, Pt, Rh, Sc, Al and other high melting point metals or conductive metal nitrides. According to an embodiment, the thickness of the top electrode layer 155 is larger than that of the bottom electrode layer 151. For example, the thickness of the bottom electrode layer 151 can be in the range of about 5 nm to about 50 nm and the thickness of the top electrode layer 155 can be in the range of about 50 nm to about 500 nm. The top electrode layer 155 is formed on the memory element layers 153, and the memory element layers 153 are formed on the bottom electrode layer 151. In the case of an MRAM, the memory element layers 153 include a magnetic tunnel junction (MTJ) structure comprising, for example, one or more magnetic fixed layers, non-magnetic barrier layers, free layers and oxide layers. The memory element layers 153 are not limited to those for an MRAM, and can include layers for memory elements of, for example, PCRAM, RRAM, ReRAM or other non-volatile memory devices. The selector device layer 149, bottom electrode layer 151, memory element layers 153 and top electrode layer 154 are deposited using, for example, one or more deposition techniques, such as, but not necessarily limited to, PVD, CVD, ALD, PECVD, RFCVD, MLD, MBD, LSMCD and/or sputtering.

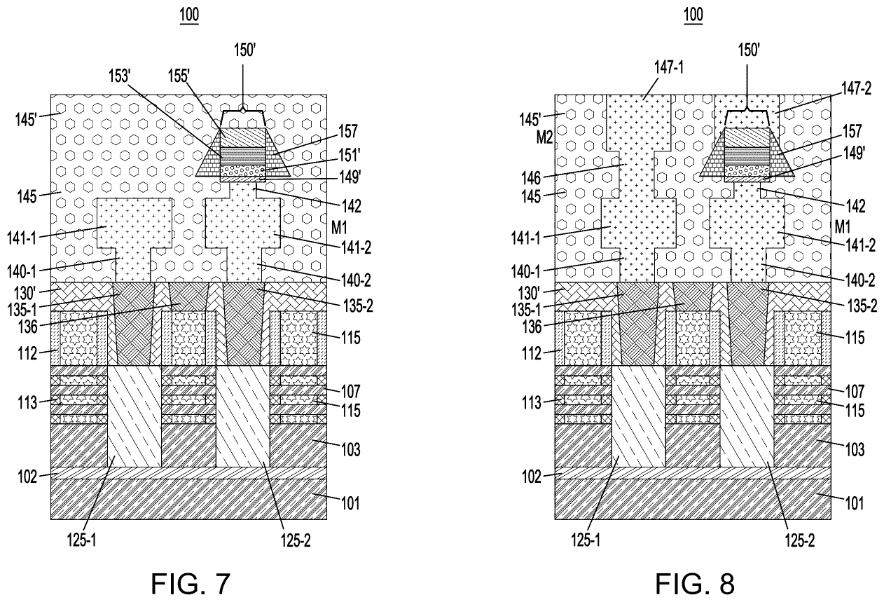

Referring to FIG. 7, the selector device layer 149 and the memory device layers 150 of the FIG. 6 structure are patterned into a selector device 149′ and a memory device 150′ (also referred to herein as a “memory cell”) comprising a top electrode 155′, a memory element 153′ comprising the plurality of patterned memory element layers 153 and a bottom electrode 151′. According to an embodiment, in a patterning process, an organic planarization layer (OPL) is formed on a first sacrificial dielectric layer and a second sacrificial dielectric layer is formed on the OPL. According to an embodiment, the second sacrificial dielectric layer includes a silicon anti-reflective coating (SiARC) layer.

The OPL includes, but is not necessarily limited to, an organic polymer including C, H, and N. In an embodiment, the OPL material can be free of silicon (Si). According to an embodiment, the OPL material can be free of Si and fluorine (F). As defined herein, a material is free of an atomic element when the level of the atomic element in the material is at or below a trace level detectable with analytic methods available in the art. Non-limiting examples of the OPL material include JSR HM8006, JSR HM8014, AZ UM10M2, Shin Etsu ODL 102, or other similar commercially available materials from such vendors as JSR, TOK, Sumitomo, Rohm & Haas, etc. The OPL can be deposited, for example, by spin coating, to a thickness of about 100 nm-about 200 nm. Photoresists are formed on the second sacrificial dielectric layer in regions corresponding to where the selector device layer 149 and the memory device layers 150 are to be patterned into a selector device 149′ and a memory device 150′.

Exposed portions of the second sacrificial dielectric layer, OPL and first sacrificial dielectric layer not under the photoresists are removed by an etching process. The etching process is performed using, for example, a fluorocarbon RIE to remove the exposed portions of the second sacrificial dielectric layer, O₂ or N₂/H₂ based RIE to etch the OPL and fluorocarbon RIE to etch first sacrificial dielectric layer down to the top electrode layer 155. According to an embodiment, the photoresists and second sacrificial dielectric layer are removed leaving the patterned OPL and first sacrificial dielectric layer. The second sacrificial dielectric layer is removed during etching of the first sacrificial dielectric layer. The OPL and the patterned first sacrificial dielectric layer remain covering the area corresponding to where the selector device 149′ and memory device 150′ will be formed.

Using the OPL and the first sacrificial dielectric layer as a mask, the top electrode layer 155 is etched into the top electrode 155′. The remaining OPL is then removed using, for example, oxygen plasma, nitrogen plasma, hydrogen plasma or other carbon strip or ashing process. The stripping process causes minimal or no damage to the remaining layers. Using the first sacrificial dielectric layer and top electrode 155′ as a mask, memory element layers 153, bottom electrode layer 151 and selector device layer 149 are patterned to result in the selector device 149′ and memory device 150′ comprising a top electrode 155′, a memory element 153′ and a bottom electrode 151′. According to an embodiment, the first sacrificial dielectric layer and part of the top electrode 155′ are removed during selector device layer 149, memory element layers 153 and bottom electrode layer 151 patterning. The patterning process includes for example, RIE and ion beam etch (IBE) processes. As can be seen in FIG. 7, the selector device 149′ is self-aligned with the top electrode 155′, memory element 153′ and bottom electrode 151′.

As shown in FIG. 7, an encapsulation layer 157 comprising, for example SiN, SiCN, SiC or other suitable material, is formed around the resulting memory device 150′ comprising the bottom electrode 151′, the memory element 153′ stacked on the bottom electrode 151′ and the top electrodes 155′ stacked on the memory element 153′. A width of the encapsulation layer 157 decreases in an upward direction to form triangular shapes.

Following the patterning process, an additional dielectric layer 145′ is added on top of the one or more dielectric layers 145. Then, referring to FIG. 8, frontside M2 contacts 147-1 and 147-2 (collectively “frontside M2 contacts 147”) are formed in the additional dielectric layer 145′ and one or more dielectric layers 145 as part of a metallization level M2. Like the frontside M1 contacts 141, the frontside M2 contacts 147 each include, for example, the same or similar fill and liner layers. A second frontside via 146 comprising a fill layer and a liner layer the same or similar to the fill and liner layers for the frontside M1 contacts 141 and the frontside M2 contacts 147, extends from the frontside M2 contact 147-1 to connect to the frontside M1 contact 141-1.

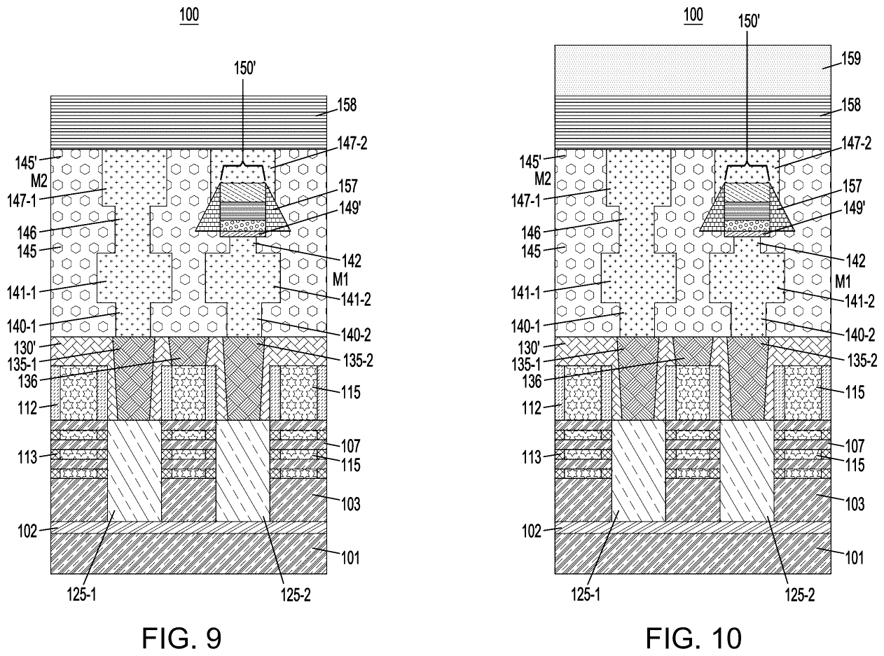

Referring to FIGS. 9 and 10, frontside BEOL interconnects 158 are formed on the structure of FIG. 8. As can be seen, the frontside M2 contacts 147 contact the frontside BEOL interconnects 158. A carrier wafer 159 is bonded to the frontside BEOL interconnects 158. The frontside BEOL interconnects 158 include various BEOL interconnect structures which may electrically connect to the frontside M2 contacts 147 and in turn to, for example, the memory device 150′, the frontside gate contact 136 and/or the frontside source/drain contacts 135. The carrier wafer 159 may be formed of materials similar to that of the first and/or second semiconductor substrates 101 and 103, and may be formed over the frontside BEOL interconnects 158 using a wafer bonding process, such as dielectric-to-dielectric bonding.

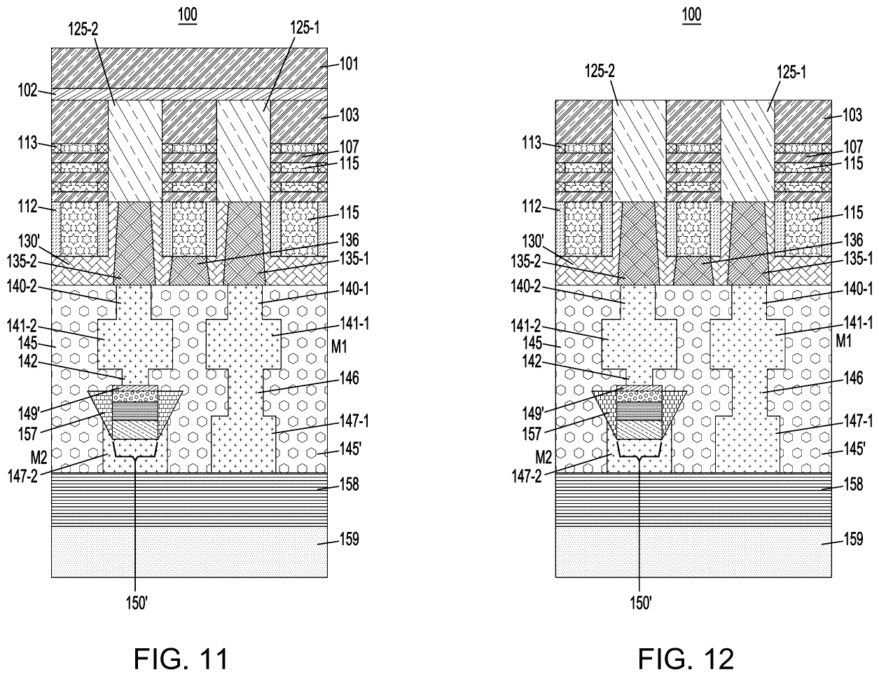

Referring to FIG. 11, using the carrier wafer 159, the semiconductor structure 100 may be “flipped” (e.g., rotated 180 degrees) so that the structure is inverted. In addition, referring to FIG. 12, the first semiconductor substrate 101 is removed from the backside of the semiconductor structure 100. The removal process, which includes grinding and etching of the first semiconductor substrate 101, stops at the etch stop layer 102. The first semiconductor substrate 101 may be grinded to remove a bulk portion of the substrate material followed by selective etching with an etchant that selectively etches silicon with respect to a material of the etch stop layer 102 (e.g., SiGe). Then, the etch stop layer 102 is removed to expose the second semiconductor substrate 103 and the source/drain regions 125. Etching processes for removal of the etch stop layer 102 include, for example, using RIE with an Ar/CHF3 based chemistry.

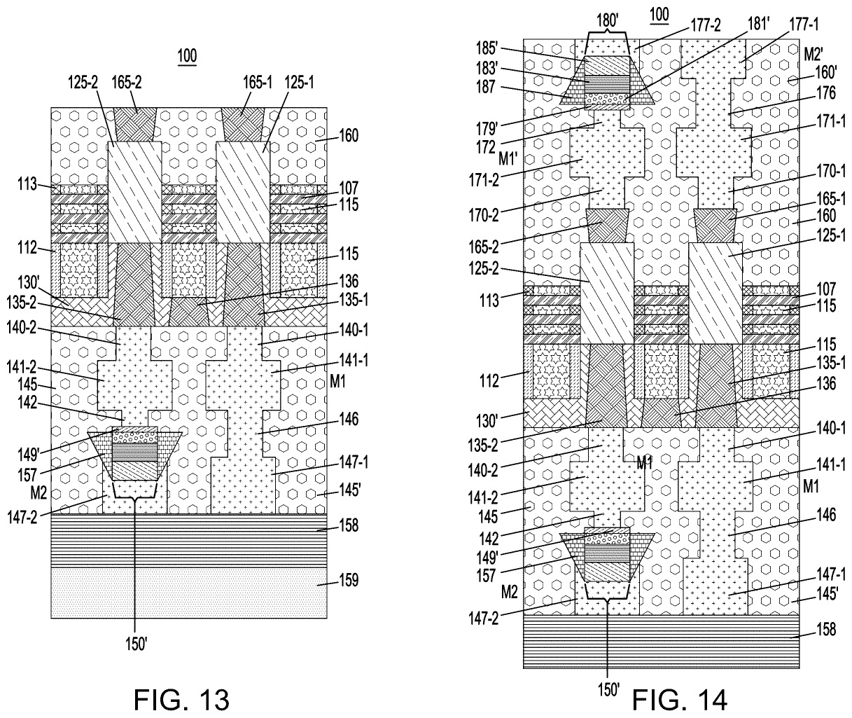

Referring to FIG. 13, the second semiconductor substrate 103 (e.g., silicon layer) is selectively removed from the semiconductor structure 100 with respect to the source/drain regions 125, wherein portions of the source/drain regions 125 are exposed. A backside ILD layer 160 is deposited to fill in areas formerly occupied by the second semiconductor substrate 103. The backside ILD layer 160 is deposited using deposition techniques such as, for example, CVD, PECVD, RFCVD, PVD, ALD, MBD, PLD, and/or LSMCD, followed by a planarization process, such as, CMP. The backside ILD layer 160 may include, for example, SiOₓ, SiOC, SiOCN or some other dielectric.

Backside source/drain contacts 165-1 and 165-2 (collectively “backside source/drain contacts 165”) are formed in the backside ILD layer 160. In forming the backside source/drain contacts 165, openings are formed through portions of the backside ILD layer 160. The openings expose portions the source/drain regions 125 on which the backside source/drain contacts 165 are to be formed. According to an embodiment, masks are formed on parts of the backside ILD layer 160, and exposed portions of the backside ILD layer 160 corresponding to where the openings are to be formed are removed using, for example, a dry etching process using a RIE or IBE process, a wet chemical etch process or a combination of these etching processes. A dry etch may be performed using a plasma. Such wet or dry etch processes include, for example, IBE by Ar/CHF3 based chemistry.

Metal layers are deposited in the openings to form the backside source/drain contacts 165. The metal layers include, for example, a silicide layer, such as Ni, Ti, NiPt, etc., a metal adhesion layer, such as TiN, and a conductive metal fill layer, such as W, Al, Co, Ru, etc., and can be deposited using, for example, a deposition technique such as CVD, PECVD, RFCVD, PVD, ALD, MBD, PLD, LSMCD, sputtering and/or plating, followed by a planarization process such as, CMP to remove excess portions of the metal layers from on top of the backside ILD layer 160.

The backside source/drain contacts 165-1 and 165-2 contact respective ones of the source/drain regions 125-1 and 125-2 at back sides of the source/drain regions 125. The backside source/drain contacts 165 extend through the backside ILD layer 160 to land on and contact the corresponding source/drain regions 125.

Referring to FIG. 14, a similar structure to what is formed on the frontside of the semiconductor structure 100 is formed on the backside of the semiconductor structure 100. In more detail, one or more additional backside ILD layers 160′ the same or similar to the one or more dielectric layers 145 are formed on the FIG. 13 structure. A metallization level M1′ formed in the one or more additional backside ILD layers 160′ includes backside M1′ contacts 171-1 and 171-2 (collectively “backside M1′ contacts 171”) each comprising, for example, a fill layer and a liner layer similar to those used in connection with the frontside M1 contacts 141. First backside vias 170-1 and 170-2 (collectively “first backside vias 170”), each comprising a fill layer and a liner layer the same or similar to the fill and liner layers for the frontside M1 contacts 141 and backside M1′ contacts 171, extend from the backside M1′ contacts 171 to connect to the backside source/drain contacts 165-1 and 165-2.

A backside bottom electrode contact 172 is formed in the one or more additional backside ILD layers 160′ on the backside M1′ contact 171-2. The backside bottom electrode contact 172 is a contact for a bottom electrode of a backside memory device that is subsequently formed on the backside bottom electrode contact 172. Similar to the frontside M1 contacts 141 and the backside M1′ contacts 171, the backside bottom electrode contact 172 includes a fill layer and a liner layer comprising the same or similar materials to those of the previously described fill and liner layers. The backside bottom electrode contact 172 is formed by etching portions of the one or more additional backside ILD layers 160′ over the backside M1′ contact 171-2 to form a trench in which the liner layer and the fill layer are deposited to fill in the trench.

Similar to the processing described in connection with FIGS. 6 and 7, a selector device layer and memory device layers formed on the backside bottom electrode contact 172 are patterned into a selector device 179′ and a memory device 180′ (also referred to herein as a “memory cell”) comprising a top electrode 185′, a memory element 183′ comprising the plurality of patterned memory element layers and a bottom electrode 181′. As can be seen in FIG. 14, the selector device 179′ is self-aligned with the top electrode 185′, memory element 183′ and bottom electrode 181′.

An encapsulation layer 187 comprising, for example SiN, SiCN, SiC or other suitable material, is formed around the resulting memory device 180′ comprising the bottom electrode 181′, the memory element 183′ stacked on the bottom electrode 181′ and the top electrode 185′ stacked on the memory element 183′. A width of the encapsulation layer 187 decreases in an upward direction to form triangular shapes.

Backside M2′ contacts 177-1 and 177-2 (collectively “backside M2′ contacts 177”) are formed in the one or more additional backside ILD layers 160′ as part of a metallization level M2′. Like the backside M1′ contacts 171, the backside M2′ contacts 177 each include, for example, the same or similar fill and liner layers. A second backside via 176 comprising a fill layer and a liner layer the same or similar to the fill and liner layers for the backside M1′ contacts 171 and the backside M2′ contacts 177, extends from the backside M2′ contact 177-1 to connect to the backside M1′ contact 171-1.

Backside BEOL interconnects (not shown) similar to the frontside BEOL interconnects 158 can be formed on the structure of FIG. 14 to electrically connect to the backside M2′ contacts 177 and in turn to, for example, the memory device 180′ and/or the backside source/drain contacts 165. The carrier wafer 159 can be removed.

The selector devices 149′ and 179′ are respectively connected to and associated with a first memory device 150′ (e.g., first MRAM cell) on a frontside of the semiconductor structure 100 and a second memory device 180′ (e.g., second MRAM cell) on a backside of the semiconductor structure 100. Each of the selector devices 149′ and 179′ may be a selector switch configured to be closed by applying a voltage across the switch. In particular, to activate the selector switch (also referred to as “closing” or “turning on” the selector switch), a voltage across the switch must be at least as large as a particular switch threshold Vs. In accordance with at least some embodiments of the present disclosure, the selector switches have the same switch threshold Vs. As discussed in further detail below, however, it is possible in alternative embodiments to configure the selector switches to have switch thresholds that are different from one another.

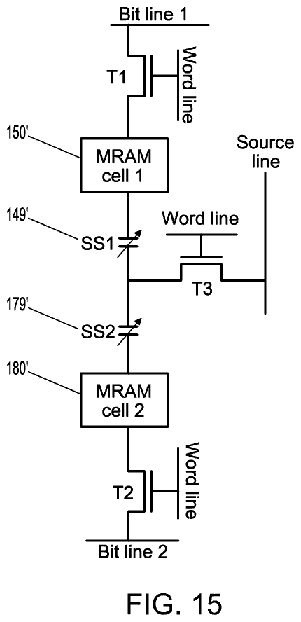

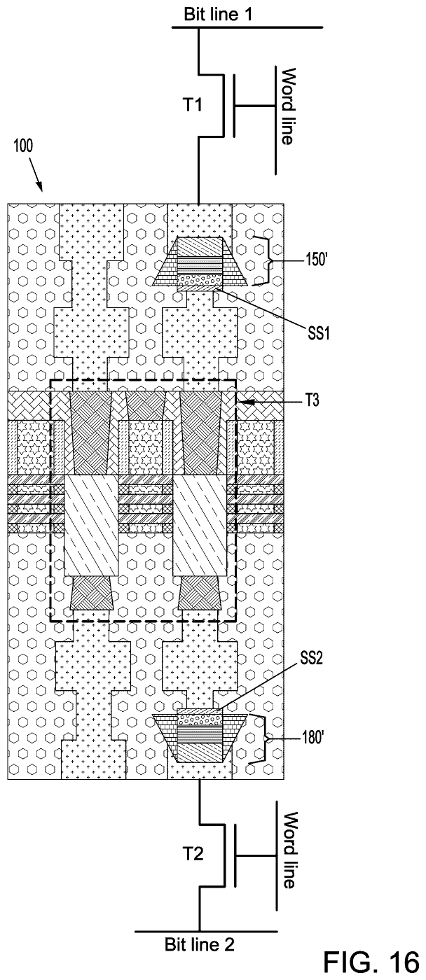

Switch threshold voltages and the configuration of the selector devices 149′ and 179′ enable the first and second memory devices 150′ and 180′ to share a common transistor (e.g., transistor T3 in FIGS. 15 and 16) to perform operations (e.g., read and/or write operations) while keeping the operations pertaining to the first memory device 150′ separate from those pertaining to the second memory device 180′.

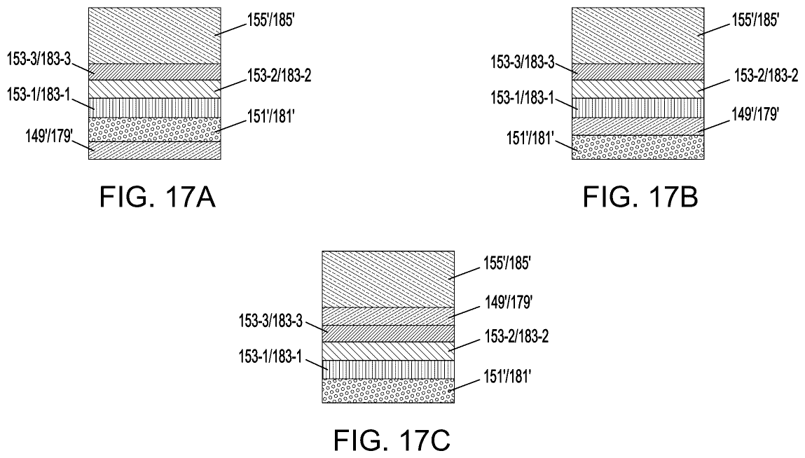

Referring to FIGS. 17A-17C, self-aligned selector device layers may be differently positioned. For example, in the configuration shown in FIG. 17A, as previously described for memory devices 150′ and 180′, the self-aligned layers for the selector devices 149′ and 179′ are disposed under a bottom electrode 151′/181′ to be between the bottom electrode 151′/181′ and a corresponding bottom electrode contact 142/172.

The configurations in FIGS. 17A-17C further illustrate layers of the memory elements 153′/183′ including reference layer 153-1/183-1, tunnel barrier layer 153-2/183-2 and free layer 153-3/183-3. In other embodiments, in the configurations shown in FIGS. 17B and 17C, respectively, the self-aligned layers for the selector devices 149′ and 179′ are disposed between reference layer 153-1/183-1 and bottom electrode 151′/181′ or between top electrode 155′/185′ and free layer 153-3/183-3.

Referring to the circuit diagram in FIG. 15 and the cross-sectional view combined with a circuit diagram in FIG. 16 illustrating the double-sided 2-bit MRAM architecture, each of 2-bit MRAM cells (e.g., memory devices 150′ and 180′) is connected to a common transistor T3 and are formed on opposite sides of a wafer to allow for memory density scaling beyond minimum allowed MRAM device pitch. Selector devices 149′ and 179′ (e.g., selector switches SS1 and SS2) are used to eliminate disturbance of a first MRAM cell during read and/or write operations of a second MRAM cell. The use of a nanosheet transistor as the common transistor (T3) provides further scaling advantages.

In FIGS. 15 and 16, T1, T2, T3 represent transistors. In illustrative embodiments, each of the transistors may be nanosheet transistors, but the embodiments are not necessarily limited thereto. SS1 and SS2 represent selector switches that are turned on by applying a threshold voltage across the selector switches. Word lines are connected to the gates of the transistors T1, T2 and T3.

In connection with write operations, a free layer of memory device 150′ (MRAM Cell 1) is programmed by passing current through memory device 150′ by turning on transistors T1 and T3, while transistor T2 is off. A free layer of memory device 180′ (MRAM Cell 2) is programmed by passing current through memory device 180′ by turning on transistors T2 and T3, while transistor T1 is off.

In more detail, while performing a write operation to program the first bit of a two-bit MRAM cell, when the bit of a first MRAM cell (e.g., memory device 150′) is to be programmed, the first and third transistors T1 and T3 are turned on which allows current to flow through the first MRAM cell to a source line, and the second transistor T2 is turned off. In contrast, when the bit of the second MRAM cell (e.g., memory device 180′) is to be programmed, the first transistor T1 is turned off and the second and third transistors T2 and T3 are turned on which allows current to flow through the second MRAM cell to the source line.

To alter the free layer in the first MRAM cell (e.g., memory device 150′), the write voltage must be above a particular write threshold Vw. The write current, which is passed along bit line 1 and through the first MRAM cell has a voltage that is at least as large as the write threshold Vw. In addition, the write threshold Vw is larger than the switch threshold Vs of the selector switch SS1. Similarly, to alter the free layer in the second MRAM cell (e.g., memory device 180′), the write voltage must be above the particular write threshold Vw. The write current, which is passed along bit line 2 and through the second MRAM cell has a voltage that is at least as large as the write threshold Vw. In addition, the write threshold Vw is larger than the switch threshold Vs of the selector switch SS2. Since the write threshold Vw is larger than the switch threshold Vs of the first or second selector switches SS1 and SS2, the write current is also sufficient to close (turn on) the first or second selector switches SS1 and SS2. The selector devices 149′/179′ may be selector switches or selector diodes.

Similar to write operations, in connection with read operations, a state of each MRAM cell is read by turning on transistors T1 and T3 or transistors T2 and T3. The respective selector devices 149′ and 179′ (e.g., selector switches SS1 and SS2) ensure respective memory devices 150′ and 180′ to be connected to the common transistor T3 at different times so that read or write operations pertaining to the first memory device 150′ remain separate from those pertaining to the second memory device 180′.

As can be understood from FIGS. 15 and 16, two MRAM cells (memory devices 150′ and 180′) are formed on two sides (e.g., frontside and backside) of a wafer, and are connected to a common transistor T3. The common transistor T3 can be, for example, a nanosheet transistor, a FinFET or MOSFET. A frontside source/drain contact 135-2 connects a source/drain region 125-2 of the common transistor T3 to a frontside MRAM cell (memory device 150′) through selector device 149′. A backside source/drain contact 165-2 connects a source/drain region 125-2 of the common transistor T3 to a backside MRAM cell (memory device 180′) through selector device 179′. As a result, one shared transistor T3 is used by two MRAM cells to perform write or read operations, and the two MRAM cells are programmed independently.

The top electrodes 155′ and 185′ of each memory device 150′ and 180′ are connected to different transistors (T1 and T2) using separate metal lines (e.g., frontside M2 contact 147-2 and backside M2′ contact 177-2). These different transistors T1 and T2 can be adjacent to common transistor T3. The frontside M1 and M2 contacts 141 and 147, and the backside M1′ and M2′ contacts 171 and 177 can be formed using, for example, damascene and/or subtractive etching processes.

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, CMOSs, MOSFETS, and/or FinFETs. By way of non-limiting example, the semiconductor devices can include, but are not limited to CMOS, MOSFET, and FinFET devices, and/or semiconductor devices that use CMOS, MOSFET, and/or FinFET technology.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor.

As noted above, the embodiments provide structures for and techniques for forming a double-sided 2-bit magnetoresistive random access memory (MRAM) device. In the illustrative embodiments, the MRAM cells are located on respective front and back sides of a wafer to allow for increases in memory density at a given pitch. The use of common transistor with independent operations controlled by respective switching devices disposed between memory cells and the common transistor reduces the total number of required transistors, thereby permitting larger sized transistors to provide higher drive currents.

In one embodiment, a semiconductor device includes a first memory cell disposed on a first side of the semiconductor device and connected to a transistor, and a second memory cell disposed on a second side of the semiconductor device and connected to the transistor. The first side of the semiconductor device is on top of the transistor and the second side of the semiconductor device is under the transistor.

The first memory cell may include a first MRAM cell connected to a first bit line, and the second memory cell may include a second MRAM cell connected to a second bit line. The transistor may include a source/drain region. The semiconductor device may further include a first source/drain contact disposed on a first side of the source/drain region on the first side of the semiconductor device, and a second source/drain contact disposed on a second side of the source/drain region on the second side of the semiconductor device. The first memory cell may be connected to the transistor through the first source/drain contact, and the second memory cell may be connected to the transistor through the second source/drain contact. The transistor may include a nanosheet transistor.

The first side of the semiconductor device may include a frontside of the semiconductor device, and the second side of the semiconductor device may include a backside of the semiconductor device. A first selector device may correspond to the first memory cell, wherein the first selector device is configured to permit current to flow from the first memory cell to the transistor when voltage applied to the first selector device is greater than or equal to a threshold activation voltage. A second selector device may correspond to the second memory cell, wherein the second selector device is configured to permit current to flow from the second memory cell to the transistor when voltage applied to the second selector device is greater than or equal to the threshold activation voltage.

The first selector device may be disposed on the first side of the semiconductor device, and the second selector device may be disposed on the second side of the semiconductor device. The first selector device may be disposed between a bottom electrode of the first memory cell and a bottom electrode contact corresponding to the first memory cell, and may be self-aligned with the bottom electrode of the first memory cell. The second selector device may be disposed between a bottom electrode of the second memory cell and a bottom electrode contact corresponding to the second memory cell, and may be self-aligned with the bottom electrode of the second memory cell. The first selector device may be disposed between a bottom electrode of the first memory cell and a reference layer of the first memory cell, and the second selector device may be disposed between a bottom electrode of the second memory cell and a reference layer of the second memory cell. The first selector device may be disposed between a top electrode of the first memory cell and a free layer of the first memory cell, and the second selector device may be disposed between a top electrode of the second memory cell and a free layer of the second memory cell.

The transistor may be a shared transistor, and a top electrode of the first memory cell may be connected to a first transistor different from the shared transistor through a first conductive line on the first side of the semiconductor device. A top electrode of the second memory cell may be connected to a second transistor different from the first transistor and the shared transistor through a second conductive line on the second side of the semiconductor device.

In another embodiment, a semiconductor device includes a first magnetoresistive random access memory cell disposed on a first side of the semiconductor device and connected to a first side of a source/drain region of a transistor, and a second magnetoresistive random access memory cell disposed on a second side of the semiconductor device and connected to a second side of the source/drain region of the transistor. The first side of the semiconductor device is on top of the transistor and the second side of the semiconductor device is under the transistor. The first side of the source/drain region corresponds to the first side of the semiconductor device, and the second side of the source/drain region corresponds to the second side of the semiconductor device.

The first side of the semiconductor device may include a frontside of the semiconductor device, and the second side of the semiconductor device includes a backside of the semiconductor device. The first selector device may correspond to the first MRAM cell, wherein the first selector device is configured to permit current to flow from the first MRAM cell to the transistor when voltage applied to the first selector device is greater than or equal to a threshold activation voltage. The second selector device may correspond to the second MRAM cell, wherein the second selector device is configured to permit current to flow from the second MRAM cell to the transistor when voltage applied to the second selector device is greater than or equal to the threshold activation voltage.

The first selector device may be disposed on the first side of the semiconductor device and is aligned with at least a bottom electrode of the first MRAM cell, and the second selector device may be disposed on the second side of the semiconductor device and is aligned with at least a bottom electrode of the second MRAM cell.

The transistor may be a shared transistor, a top electrode of the first MRAM cell is connected to a first transistor different from the shared transistor through a first conductive line on the first side of the semiconductor device, and a top electrode of the second MRAM cell is connected to a second transistor different from the first transistor and the shared transistor through a second conductive line on the second side of the semiconductor device.

In another embodiment, a semiconductor device includes a stacked structure comprising a transistor, a first memory cell stacked over the transistor, and a second memory cell stacked under the transistor. The transistor is connected to the first memory cell and to the second memory cell. The first memory cell is disposed on a first side of the semiconductor device and the second memory cell is disposed on a second side of the semiconductor device.

The transistor may include a source/drain region, and the semiconductor device may further include a first source/drain contact disposed on a first side of the source/drain region on the first side of the semiconductor device, and a second source/drain contact disposed on a second side of the source/drain region on the second side of the semiconductor device. The first memory cell may be connected to the transistor through the first source/drain contact, and the second memory cell may be connected to the transistor through the second source/drain contact.

The first side of the semiconductor device may include a frontside of the semiconductor device, and the second side of the semiconductor device may include a backside of the semiconductor device. The transistor may be a shared transistor. A top electrode of the first memory cell may be connected to a first transistor different from the shared transistor through a first conductive line on the first side of the semiconductor device, and a top electrode of the second memory cell may be connected to a second transistor different from the first transistor and the shared transistor through a second conductive line on the second side of the semiconductor device.

It should be understood that the various layers, structures, and regions shown in the figures are schematic illustrations that are not drawn to scale. In addition, for ease of explanation, one or more layers, structures, and regions of a type commonly used to form semiconductor devices or structures may not be explicitly shown in a given figure. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

Moreover, the same or similar reference numbers are used throughout the figures to denote the same or similar features, elements, or structures, and thus, a detailed explanation of the same or similar features, elements, or structures are not repeated for each of the figures. It is to be understood that the terms “approximately” or “substantially” as used herein with regard to thicknesses, widths, percentages, ranges, temperatures, times and other process parameters, etc., are meant to denote being close or approximate to, but not exactly. For example, the term “approximately” or “substantially” as used herein implies that a small margin of error is present, such as ±5%, preferably less than 2% or 1% or less than the stated amount.

In the description above, various materials, dimensions and processing parameters for different elements are provided. Unless otherwise noted, such materials are given by way of example only and embodiments are not limited solely to the specific examples given. Similarly, unless otherwise noted, all dimensions and process parameters are given by way of example and embodiments are not limited solely to the specific dimensions or ranges given.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device comprising:
a first memory cell disposed on a first side of the semiconductor device and connected to a transistor; and
a second memory cell disposed on a second side of the semiconductor device and connected to the transistor;
wherein the first side of the semiconductor device is on top of the transistor and the second side of the semiconductor device is under the transistor.

2. The semiconductor device of claim 1, wherein:
the first memory cell comprises a first magnetoresistive random access memory cell connected to a first bit line; and
the second memory cell comprises a second magnetoresistive random access memory cell connected to a second bit line.

3. The semiconductor device of claim 1, wherein:
the transistor comprises a source/drain region;
the semiconductor device further comprises a first source/drain contact disposed on a first side of the source/drain region on the first side of the semiconductor device, and a second source/drain contact disposed on a second side of the source/drain region on the second side of the semiconductor device;
the first memory cell is connected to the transistor through the first source/drain contact; and
the second memory cell is connected to the transistor through the second source/drain contact.

4. The semiconductor device of claim 1, wherein the transistor comprises a nanosheet transistor.

5. The semiconductor device of claim 1, wherein the first side of the semiconductor device comprises a frontside of the semiconductor device, and the second side of the semiconductor device comprises a backside of the semiconductor device.

6. The semiconductor device of claim 1, further comprising:
a first selector device corresponding to the first memory cell, wherein the first selector device is configured to permit current to flow from the first memory cell to the transistor when voltage applied to the first selector device is greater than or equal to a threshold activation voltage; and
a second selector device corresponding to the second memory cell, wherein the second selector device is configured to permit current to flow from the second memory cell to the transistor when voltage applied to the second selector device is greater than or equal to the threshold activation voltage.

7. The semiconductor device of claim 6, wherein:
the first selector device is disposed on the first side of the semiconductor device; and
the second selector device is disposed on the second side of the semiconductor device.

8. The semiconductor device of claim 6, wherein:
the first selector device is disposed between a bottom electrode of the first memory cell and a bottom electrode contact corresponding to the first memory cell, and is self-aligned with the bottom electrode of the first memory cell; and
the second selector device is disposed between a bottom electrode of the second memory cell and a bottom electrode contact corresponding to the second memory cell, and is self-aligned with the bottom electrode of the second memory cell.

9. The semiconductor device of claim 6, wherein:
the first selector device is disposed between a bottom electrode of the first memory cell and a reference layer of the first memory cell; and
the second selector device is disposed between a bottom electrode of the second memory cell and a reference layer of the second memory cell.

10. The semiconductor device of claim 6, wherein:
the first selector device is disposed between a top electrode of the first memory cell and a free layer of the first memory cell; and
the second selector device is disposed between a top electrode of the second memory cell and a free layer of the second memory cell.

11. The semiconductor device of claim 1, wherein:
the transistor is a shared transistor;
a top electrode of the first memory cell is connected to a first transistor different from the shared transistor through a first conductive line on the first side of the semiconductor device; and
a top electrode of the second memory cell is connected to a second transistor different from the first transistor and the shared transistor through a second conductive line on the second side of the semiconductor device.

12. A semiconductor device comprising:
a first magnetoresistive random access memory cell disposed on a first side of the semiconductor device and connected to a first side of a source/drain region of a transistor; and
a second magnetoresistive random access memory cell disposed on a second side of the semiconductor device and connected to a second side of the source/drain region of the transistor;
wherein the first side of the semiconductor device is on top of the transistor and the second side of the semiconductor device is under the transistor; and
wherein the first side of the source/drain region corresponds to the first side of the semiconductor device, and the second side of the source/drain region corresponds to the second side of the semiconductor device.

13. The semiconductor device of claim 12, wherein the first side of the semiconductor device comprises a frontside of the semiconductor device, and the second side of the semiconductor device comprises a backside of the semiconductor device.

14. The semiconductor device of claim 12, further comprising:
a first selector device corresponding to the first magnetoresistive random access memory cell, wherein the first selector device is configured to permit current to flow from the first magnetoresistive random access memory cell to the transistor when voltage applied to the first selector device is greater than or equal to a threshold activation voltage; and
a second selector device corresponding to the second magnetoresistive random access memory cell, wherein the second selector device is configured to permit current to flow from the second magnetoresistive random access memory cell to the transistor when voltage applied to the second selector device is greater than or equal to the threshold activation voltage.

15. The semiconductor device of claim 14, wherein:
the first selector device is disposed on the first side of the semiconductor device and is aligned with at least a bottom electrode of the first magnetoresistive random access memory cell; and
the second selector device is disposed on the second side of the semiconductor device and is aligned with at least a bottom electrode of the second magnetoresistive random access memory cell.

16. The semiconductor device of claim 12, wherein:
the transistor is a shared transistor;
a top electrode of the first magnetoresistive random access memory cell is connected to a first transistor different from the shared transistor through a first conductive line on the first side of the semiconductor device; and
a top electrode of the second magnetoresistive random access memory cell is connected to a second transistor different from the first transistor and the shared transistor through a second conductive line on the second side of the semiconductor device.

17. A semiconductor device comprising:
a stacked structure comprising:
a transistor;
a first memory cell stacked over the transistor; and
a second memory cell stacked under the transistor;
wherein the transistor is connected to the first memory cell and to the second memory cell; and
wherein the first memory cell is disposed on a first side of the semiconductor device and the second memory cell is disposed on a second side of the semiconductor device.

18. The semiconductor device of claim 17, wherein:
the transistor comprises a source/drain region;
the semiconductor device further comprises a first source/drain contact disposed on a first side of the source/drain region on the first side of the semiconductor device, and a second source/drain contact disposed on a second side of the source/drain region on the second side of the semiconductor device;
the first memory cell is connected to the transistor through the first source/drain contact; and
the second memory cell is connected to the transistor through the second source/drain contact.

19. The semiconductor device of claim 17, wherein the first side of the semiconductor device comprises a frontside of the semiconductor device, and the second side of the semiconductor device comprises a backside of the semiconductor device.

20. The semiconductor device of claim 17, wherein:
the transistor is a shared transistor;
a top electrode of the first memory cell is connected to a first transistor different from the shared transistor through a first conductive line on the first side of the semiconductor device; and
a top electrode of the second memory cell is connected to a second transistor different from the first transistor and the shared transistor through a second conductive line on the second side of the semiconductor device.
